(19) United States
(12) Patent Application Publication
(10) Pub. No.: US 2007/0284593 A1
(43) Pub. Date: Dec. 13, 2007

(54) Nitride-based semiconductor light emitting diode

(75) Inventors: Kun Yoo Ko, Hwaseong (KR); Bang Won Oh, Seongnam (KR); Seok Min Hwang, Suwon (KR); Je Won Kim, Suwon (KR); Hyung Jin Park, Suwon (KR); Dong Woo Kim, Seoul (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 11/798,677

(22) Filed: May 16, 2007

(30) Foreign Application Priority Data
May 16, 2006 (KR) 10-2006-0043986

(51) Int. Cl. H01L 33/00; H01L 31/12; H01L 27/15; H01L 29/26

(52) U.S. Cl. 257/79

(57) ABSTRACT

A nitride-based semiconductor LED comprises a substrate; an n-type nitride semiconductor layer formed on the substrate; an active layer formed on a predetermined region of the n-type nitride semiconductor layer; a p-type nitride semiconductor layer formed on the active layer; a p-electrode formed on the p-type nitride semiconductor layer, the p-electrode having a p-type branch electrode; a p-type ESD pad formed at the end of the p-type branch electrode, the p-type ESD pad having a larger width than the end of the p-type branch electrode; an n-electrode formed on the n-type nitride semiconductor layer, on which the active layer is not formed, the n-electrode having an n-type branch electrode; and an n-type ESD pad formed at the end of the n-type branch electrode, the n-type ESD pad having a larger width than the end of the n-type branch electrode.

### CROSS-REFERENCE TO RELATED APPLICATIONS

This application claims the benefit of Korean Patent Application No. 10-2006-0043986 filed with the Korean Intellectual Property Office on May 16, 2006, the disclosure of which is incorporated herein by reference.

### BACKGROUND OF THE INVENTION

1. Field of the Invention

The present invention relates to a nitride-based semiconductor light emitting diode in which a p-electrode and an n-electrode having high resistance to electrostatic discharge (hereinafter, referred to as ESD) have a lateral structure.

2. Description of the Related Art

In general, light emitting diodes (hereinafter, referred to as LEDs) are semiconductor elements which convert an electrical signal into infrared rays, visible rays, or light by using a characteristic of compound semiconductor, i.e., a recombination of electrons and holes, in order to send and receive signals.

LEDs are generally used in home appliances, remote controls, electric sign boards, displays, various automation equipments, optical communication and the like, and are roughly divided into IREDs (infrared emitting diode) and VLEDs (visible light emitting diode).

In LEDs, the frequency (or wavelength) of light to be emitted is a band gap function of a material used in a semiconductor element. When a semiconductor material having a small band gap is used, photons having low energy and a long wavelength are generated. When a semiconductor material having a wide band gap is used, photons having a short wavelength are generated. Therefore, depending on a type of light to be emitted, a semiconductor material of the LED is selected.

For example, in a case of a red LED, AlGaInP is used. In a case of a blue LED, silicon carbide (SiC) and Group III nitride-based semiconductor, particularly gallium nitride (GaN), are used. Recently, as for the nitride-based semiconductor used as a blue LED, a material having a compositional formula of (AlₓIn₁₋ₓ)_{y}Ga_{1-y}N (herein, 0≦x≦1, 0≦y≦1, and 0≦x+y≦1) is widely used.

In general, such a nitride-based semiconductor LED can be grown on a sapphire substrate that is an insulating substrate. Therefore, both a p-electrode and an n-electrode should be formed horizontally in a crystal-grown semiconductor layer. Such a structure of the conventional nitride-based semiconductor LED is schematically shown in FIGS. 1 and 2.

Now, the conventional nitride-based semiconductor LED will be described in detail with reference to FIGS. 1 and 2.

FIG. 1 is a plan view illustrating the structure of the conventional nitride-based semiconductor LED, and FIG. 2 is a cross-sectional view taken along II-II′ line of FIG. 1.

Referring to FIGS. 1 and 2, the conventional nitride-based semiconductor LED includes a buffer layer 110 formed of GaN, an n-type nitride semiconductor layer 120, an active layer 130, and a p-type nitride semiconductor layer 140, which are sequentially laminated on an optically-transparent sapphire substrate 100. The active layer 130 has a single-quantum well structure containing InGaN or a multi-quantum well structure containing InGaN.

Portions of the p-type nitride semiconductor layer 140 and the active layer 130 are removed by mesa-etching such that a portion of the top surface of the n-type nitride semiconductor layer 120 is exposed. On the exposed n-type nitride semiconductor layer 120, an n-electrode 150 is formed. On the p-type nitride semiconductor layer 140, a p-electrode 160 is formed.

The conventional nitride-based semiconductor LED has such a lateral structure that the n-electrode 150 and the p-electrode 160 are formed in parallel to each other in the semiconductor layer which is crystal-grown from the sapphire substrate 100. Therefore, as the p-electrode 160 is away from the n-electrode 150, a current flow path is lengthened so that the resistance of the n-type nitride semiconductor layer 120 increases. Accordingly, currents are crowded in the vicinities of the n-electrode 150, thereby degrading a current spreading effect.

In order to solve such a problem, the n-electrode 150 and the p-electrode 160 further include an n-type branch electrode 150a and a p-type branch electrode 160a, respectively, of which each is formed so as to extend therefrom in one direction, as shown in FIG. 3. Then, the distance between the n-electrode 150 and the p-electrode 160 is maintained to be identical, thereby improving a current spreading effect.

The n-type branch electrode 150a extending from the n-electrode 150 and the p-type branch electrode 160a extending from the p-electrode 160 are spaced from each other such that a distance between the n-electrode 150 and the p-electrode 160, that is, the length of a current flow path is maintained to be uniform. Therefore, a current spreading effect is enhanced. However, the ends of the n-type and p-type branch electrodes 150a and 160a have a smaller width than the n-electrode 150 and the p-electrode 160. Therefore, when a large current is applied, the ends of the n-type and p-type branch electrodes 150a and 160a (refer to “A” of FIG. 3) can be damaged by a sudden surge voltage or static electricity, because the ends thereof have low resistance to ESD.

As a result, such a structure acts as a main cause which unstabilizes a characteristic of the nitride-based semiconductor LED, thereby reducing the reliability and production yield of the nitride-based semiconductor LED.

### SUMMARY OF THE INVENTION

An advantage of the present invention is that it provides a high-luminance nitride-based semiconductor LED which can optimize a current spreading effect, and simultaneously, minimize ESD impact, thereby stabilizing a characteristic thereof from high static electricity.

Additional aspect and advantages of the present general inventive concept will be set forth in part in the description which follows and, in part, will be obvious from the description, or may be learned by practice of the general inventive concept.

According to an aspect of the invention, a nitride-based semiconductor LED comprises a substrate; an n-type nitride semiconductor layer formed on the substrate; an active layer formed on a predetermined region of the n-type nitride semiconductor layer; a p-type nitride semiconductor layer formed on the active layer; a p-electrode formed on the p-type nitride semiconductor layer, the p-electrode having a p-type branch electrode; a p-type ESD pad formed at the end of the p-type branch electrode, the p-type ESD pad having a larger width than the end of the p-type branch electrode; an n-electrode formed on the n-type nitride semiconductor layer, on which the active layer is not formed, the n-electrode having an n-type branch electrode; and an n-type ESD pad formed at the end of the n-type branch electrode, the n-type ESD pad having a larger width than the end of the n-type branch electrode.

According to another aspect of the invention, the n-type and p-type branch electrodes, respectively, are composed of one or more lines, the line being selected from a group consisting of a straight line, a curved line, and a looped line.

According to a further aspect of the invention, the n-type and p-type branch electrodes are formed so as to extend from the n-electrode and the p-electrode, respectively, in one direction.

According to a still further aspect of the invention, the n-electrode and the p-electrode are formed in a shape selected from a group consisting of a circular shape, a polygonal shape, and another polygonal shape of which the corner is formed in a curved line.

According to a still further aspect of the invention, the n-type and p-type ESD pads are formed in a shape selected from a group consisting of a circular shape, a polygonal shape, and another polygonal shape of which the corner is formed in a curved line.

According to a still further aspect of the invention, the n-type and p-type ESD pads are formed of the same material as the n-electrode and the p-electrode, respectively.

According to a still further aspect of the invention, the n-type and p-type ESD pads are formed of a different material from the n-electrode and the p-electrode, respectively.

According to a still further aspect of the invention, the nitride-based semiconductor LED further comprises a transparent conductive layer formed between the p-type nitride semiconductor layer and the p-electrode. The transparent conductive layer increases an injection area of current to be injected through the p-electrode, thereby enhancing a current spreading effect.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a plan view illustrating the structure of a conventional nitride-based semiconductor LED;

FIG. 2 is a sectional view taken along II-II′ line of FIG. 1;

FIG. 3 is a plan view illustrating the structure of another conventional nitride-based semiconductor LED;

FIG. 4 is a plan view illustrating the structure of a nitride-based semiconductor LED according to a first embodiment of the present invention;

FIG. 5 is a sectional view taken along V-V′ line of FIG. 4;

FIGS. 6A to 6C are plan views illustrating the structures of nitride-based semiconductor LEDs according to modifications of the first embodiment of the invention;

FIG. 7 is a plan view illustrating the structure of a nitride-based semiconductor LED according to a second embodiment of the invention; and

FIG. 8 is a plan view illustrating a modified example of a p-type branch electrode of a nitride-based semiconductor LED according to an embodiment of the invention.

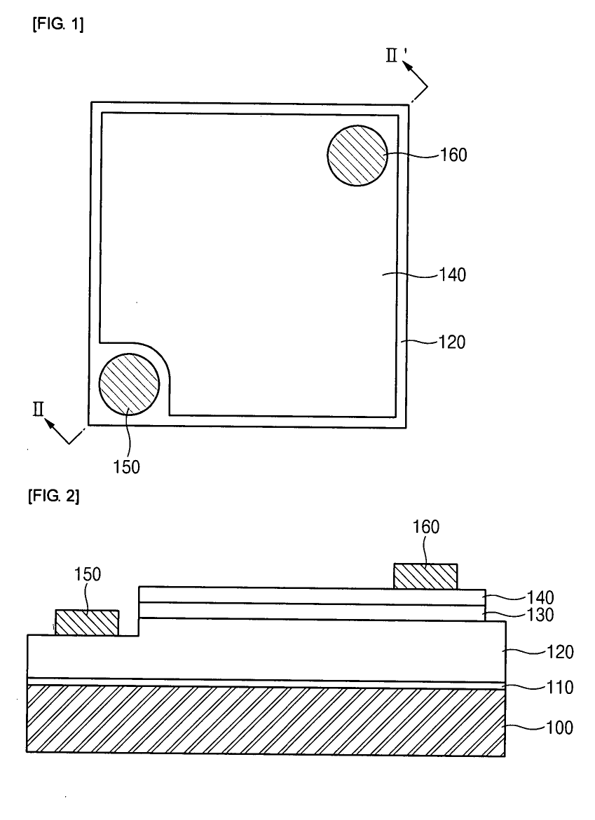

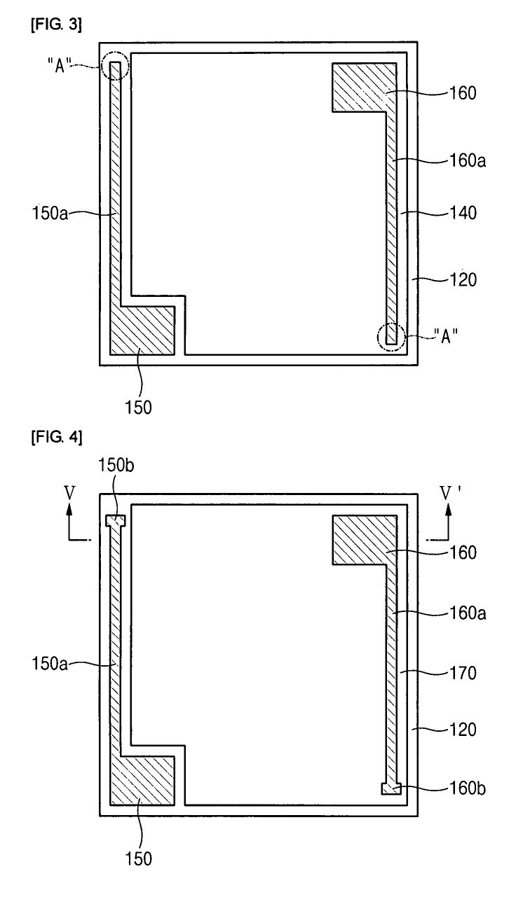

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures.

Hereinafter, embodiments of the present invention will be described in detail with reference to the accompanying drawings.

### First Embodiment

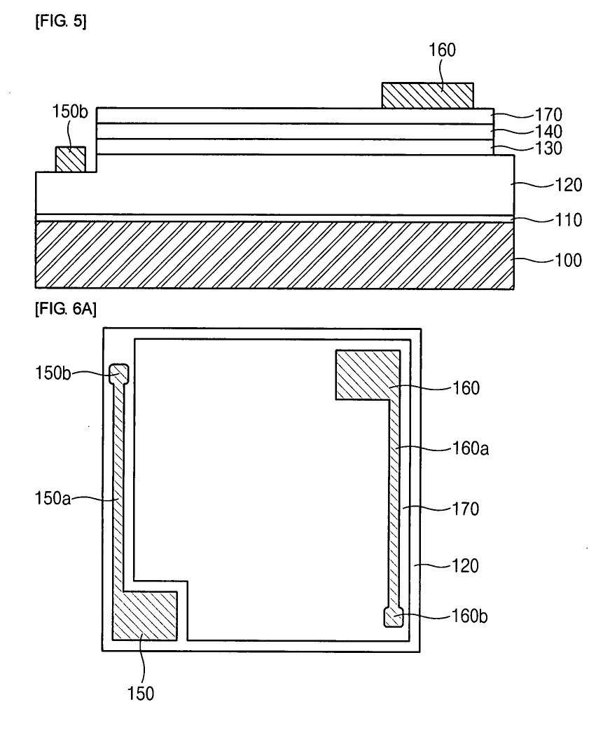

First, a nitride-based semiconductor LED according to a first embodiment of the invention will be described with reference to FIGS. 4 and 5.

FIG. 4 is a plan view illustrating the structure of the nitride-based semiconductor LED according to the first embodiment of the invention, and FIG. 5 is a sectional view taken along IV-IV′ line of FIG. 4.

As shown in FIGS. 4 and 5, the nitride-based semiconductor LED according to the first embodiment of the invention includes an optically-transparent substrate 100 and a light-emitting structure in which a buffer layer 110, an n-type nitride semiconductor layer 120, an active layer 130, and a p-type nitride semiconductor layer 140 are sequentially laminated on the substrate 100.

The substrate 100 may be a heterogeneous substrate, such as a sapphire substrate and a silicon carbide (SiC) substrate, or a homogeneous substrate such as a nitride substrate, which is suitable for growing nitride semiconductor single crystal.

The buffer layer 110 is a layer for enhancing the lattice matching with the substrate 100 before the n-type nitride semiconductor layer 120 is grown. In general, the buffer layer 110 is formed of GaN or a nitride containing Ga and can be omitted depending on a characteristic of a diode or a process condition.

The n-type nitride semiconductor layer 120, the active layer 130, and the p-type nitride semiconductor layer 140 can be composed of a semiconductor material having a compositional formula of In ₓAl_{y}Ga_{1-x-y}N (0≦X≦1, 0≦Y≦1, 0≦X+Y≦1). More specifically, the n-type nitride semiconductor layer 120 can be formed of a GaN or GaN/AlGaN layer doped with n-type conductive impurities. As for the n-type conductive impurities, Si, Ge, Sn and the like are used. Preferably, Si is mainly used. Further, the p-type nitride semiconductor layer 140 can be formed of a GaN or GaN/AlGaN layer doped with p-type conductive impurities. As for the p-type conductive impurities, Mg, Zn, Be and the like are used. Preferably, Mg is mainly used. Further, the active layer 130 can be formed of an InGaN/GaN layer having a multi-quantum well structure.

Portions of the active layer 130 and the p-type nitride semiconductor layer 140 are removed by mesa-etching such that a portion of the top surface of the n-type nitride semiconductor layer 120 is exposed.

On a predetermined portion of the n-type nitride semiconductor layer 120 exposed by the mesa-etching, an n-electrode 150 is formed. The n-electrode 150 is composed of Cr/Au and can be formed in a circular shape, a polygonal shape, or another polygonal shape of which the corner is formed in a curved line. Further, depending on a characteristic of a diode, one or more n-electrodes 150 can be formed. In this embodiment, the n-electrode 150 formed in a rectangular shape is shown (refer to FIG. 4).

On the n-type nitride semiconductor layer 120 exposed by the mesa-etching, an n-type branch electrode 150a is formed so as to extend from the n-electrode 150 in one direction. The n-type branch electrode 150a is formed with one line, the n-type branch electrode 150a having an end of which the width is smaller than that of the n-electrode 150. The line may be a line selected from a group consisting of a straight line, a curved line, and a looped curve. In this embodiment, the n-type branch electrode 150a formed in a straight line is shown.

However, since the n-type branch electrode 150a, having one end of which the width is smaller than that of the n-electrode 150, extends from the n-electrode 150 in one direction, the end of the n-type branch electrode 150a can be damaged by a sudden surge voltage or static electricity, when a large current is applied. The reason is that the end of the n-type branch electrode 150a has low resistance to ESD.

Therefore, in order that the end of the n-type branch electrode 150a has high resistance to ESD, an n-type ESD pad 150b is formed at the end of the n-type branch electrode 150a, the n-type ESD pad 150 having a larger width than the n-type branch electrode 150a. The n-type ESD pad 150a can be formed of the same material as or a different material from the n-electrode 150, depending on a characteristic of a diode and a process condition.

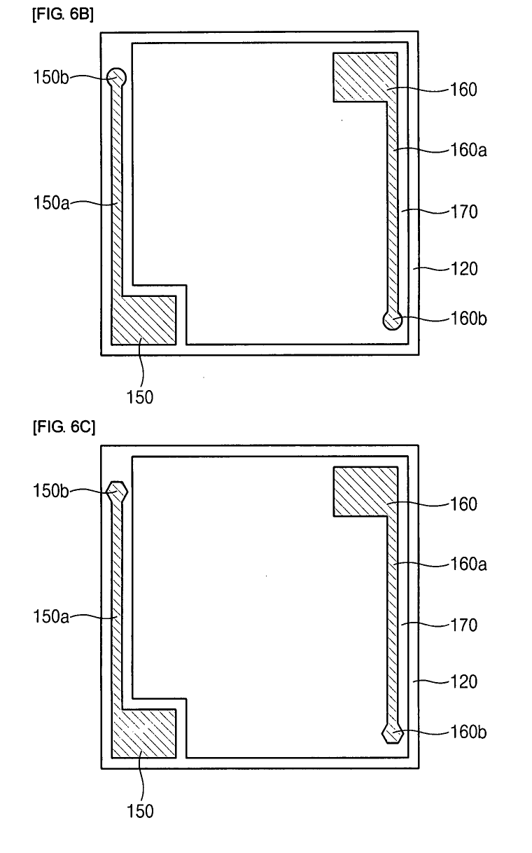

FIGS. 6A to 6C are plan views illustrating the structures of nitride-based semiconductor LEDs according to modifications of the first embodiment of the invention.

On the p-type nitride semiconductor layer 140, a transparent conductive layer 170 for increasing a current spreading effect is formed. The transparent conductive layer 170 can be formed of conductive metallic oxide such as ITO (indium tin oxide). Further, the transparent conductive layer 170 can also be formed of a metallic thin film having high conductivity and low contact resistance, if the metallic thin film has high transmittance with respect to a light-emission wavelength of an LED.

On the transparent electrode 170, a p-electrode 160 is formed.

The p-electrode 160 is composed of Cr/Au, similar to the above-described n-electrode 150. Further, the p-electrode 160 is formed in a circular shape, a polygonal shape, or another polygonal shape of which the corner is formed in a curved line. One or more p-electrodes 160 can be formed, depending on a characteristic of a diode.

A p-type branch electrode 160a is formed so as to extend from the p-electrode 160 in one direction. The p-type branch electrode 160 is formed with a line, the p-type branch electrode 160 having an end of which the width is smaller than that of the p-electrode 160. Preferably, the line may be selected from a group consisting of a straight line, a curved line, and a looped line. More specifically, FIG. 4 illustrates the p-type branch electrode 160a formed in a straight line, and FIG. 8 illustrates a p-type branch electrode 160a formed in a curved line.

The p-type branch electrode 160a is formed so as to extend from the p-electrode 160 in one direction, the p-type branch electrode 160a having an end of which the width is smaller than that of the p-electrode 160. Therefore, when a large current is applied, the end of the p-type branch electrode 160a having low resistance to ESD can be damaged by a sudden surge voltage or static electricity.

Therefore, in order that the end of the p-type branch electrode 160a has high resistance to ESD, a p-type ESD pad 160b is provided at the end of the p-type branch electrode 160a, the p-type ESD 160b having a larger width than the end of the p-type branch electrode 160a. The p-type ESD pad 160b can be formed of the same material as or a different material from the n-electrode 160, depending on a characteristic of a diode and a process condition.

In this embodiment, the n-type and p-type ESD pads 150b and 160b formed in a rectangular shape are shown. Without being limited thereto, however, the n-type and p-type ESD pads 150b and 160b can be formed in a circular shape, a polygonal shape, or another polygonal shape, of which the corner is formed in a curved line, as shown in FIGS. 6A to 6C. The n-type and p-type ESD pads 150b and 160b have a larger width than the ends of the p-type and n-type branch electrodes 150a and 160a, respectively.

### Second Embodiment

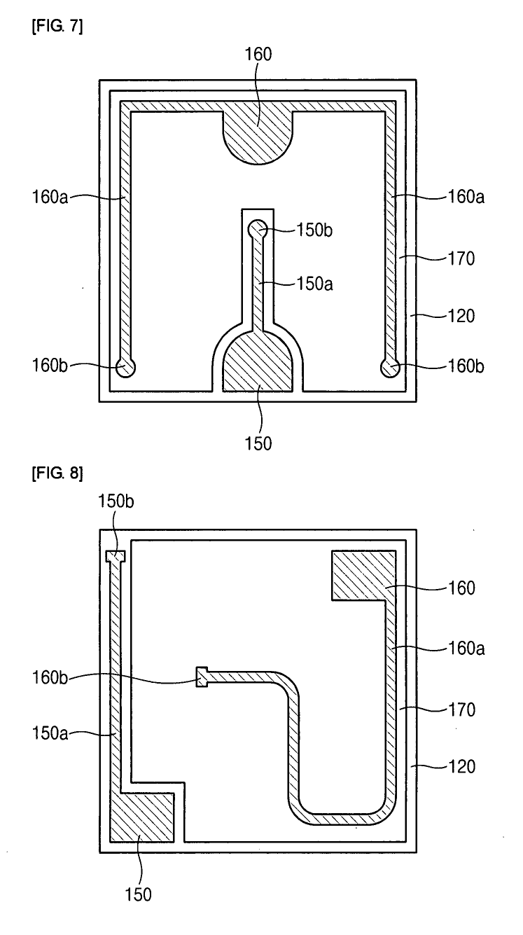

Now, a nitride-based semiconductor LED according to a second embodiment of the invention will be described in detail with reference to FIG. 7. However, the descriptions of the same components of the second embodiment as those of the first embodiment will be omitted.

FIG. 7 is a plan view illustrating the structure of the nitride-based semiconductor LED according to the second embodiment.

As shown in FIG. 7, the nitride-based semiconductor LED according to the second embodiment has almost the same construction as the nitride-based semiconductor LED according to the first embodiment. In the second embodiment, however, an n-type electrode 150 and a p-type electrode 160 are formed in a hemispherical shape, not a rectangular shape. Further, two p-type branch electrodes 160a are disposed in a finger shape such that the p-type branch electrodes 160a are parallel to each other.

Similar to the first embodiment, n-type and p-type ESD pads 150b and 160b are formed at the ends of the n-type and p-type branch electrodes 150a and 160a, respectively, the n-type and p-type ESD pads 150b and 160b having a larger width than the ends of the type and p-type branch electrodes 150a and 160a. Therefore, it is possible to obtain the same operation and effect.

In this embodiment, since the n-type and p-type branch electrodes 150a and 160a are formed with a finger structure, it is possible to enhance current spreading efficiency of a large-area nitride-based semiconductor LED which needs a large current.

As described above, the ESD pads having a larger width than the ends of the n-type and the p-type branch electrodes are respectively provided at the ends of the n-type and the p-type branch electrodes which are formed so as to extend from the n-electrode and the p-electrode. Therefore, a current spreading effect can be enhanced. Simultaneously, the resistance to ESD at the ends of the n-type and the p-type branch electrodes can be increased, thereby preventing the nitride-based semiconductor LED from being damaged from a sudden surge voltage or static electricity.

Therefore, it is possible to provide a high-luminance nitride-based semiconductor LED which is stabilized from ESD.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A nitride-based semiconductor LED comprising:
a substrate;
an n-type nitride semiconductor layer formed on the substrate;
an active layer formed on a predetermined region of the n-type nitride semiconductor layer;
a p-type nitride semiconductor layer formed on the active layer;
a p-electrode formed on the p-type nitride semiconductor layer, the p-electrode having a p-type branch electrode;
a p-type ESD pad formed at the end of the p-type branch electrode, the p-type ESD pad having a larger width than the end of the p-type branch electrode;
an n-electrode formed on the n-type nitride semiconductor layer, on which the active layer is not formed, the n-electrode having an n-type branch electrode; and
an n-type ESD pad formed at the end of the n-type branch electrode, the n-type ESD pad having a larger width than the end of the n-type branch electrode.

2. The nitride-based semiconductor LED according to claim 1,
wherein the n-type and p-type branch electrodes, respectively, are composed of one or more lines, the line being selected from a group consisting of a straight line, a curved line, and a looped line.

3. The nitride-based semiconductor LED according to claim 2,
wherein the n-type and p-type branch electrodes are formed so as to extend from the n-electrode and the p-electrode, respectively, in one direction.

4. The nitride-based semiconductor LED according to claim 1,
wherein the n-electrode and the p-electrode are formed in a shape selected from a group consisting of a circular shape, a polygonal shape, and another polygonal shape of which the corner is formed in a curved line.

5. The nitride-based semiconductor LED according to claim 1,
wherein the n-type and p-type ESD pads are formed in a shape selected from a group consisting of a circular shape, a polygonal shape, and another polygonal shape of which the corner is formed in a curved line.

6. The nitride-based semiconductor LED according to claim 1,
wherein the n-type and p-type ESD pads are formed of the same material as the n-electrode and the p-electrode, respectively.

7. The nitride-based semiconductor LED according to claim 1,
wherein the n-type and p-type ESD pads are formed of a different material from the n-electrode and the p-electrode, respectively.

8. The nitride-based semiconductor LED according to claim 1 further comprising
a transparent conductive layer formed between the p-type nitride semiconductor layer and the p-electrode.
